(19) United States
(12) Patent Application Publication
(10) Pub. No.: US 2007/0094558 A1
(43) Pub. Date: Apr. 26, 2007

(54) Apparatus and method for testing an IEEE1394 port

(75) Inventors: Chia-Ching Yi, Tu-cheng (TW); Tsai-Sheng Wen, Tu-cheng (TW); Chao-Tsung Fan, Tu-cheng (TW); Kuan-Neng Wang, Tu-cheng (TW); Ming-Shiu Ou Yang, Tu-cheng (TW); Wei-Yuan Chen, Tu-cheng (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/520,135

(22) Filed: Sep. 13, 2006

(30) Foreign Application Priority Data
Oct. 24, 2005 (CN) 200510100597.8

(51) Int. Cl. G01R 31/28; G06F 3/06; G06F 13/38

(52) U.S. Cl. 714/724; 710/62; 711/4

(57) ABSTRACT

An apparatus for testing an IEEE1394 port of a motherboard test device includes an IEEE1394 connector, a cable transceiver arbiter connected to the IEEE1394 connector, a first converting chip connected to the cable transceiver arbiter, a second converting chip connected to the first converting chip, and a flash chip connected to the second converting chip. The controller receives IEEE1394 signals from the connector, the first converting chip and second converting chip cooperate to convert the IEEE1394 signals to flash signals, the flash signals are stored in the flash chip. The first converting chip and the second converting chip also cooperate to convert the flash signals to the IEEE1394 signals, the connector outputs the IEEE1394 signals through the controller. A method for testing an IEEE1394 port of a motherboard test device is also provided.

### BACKGROUND OF THE INVENTION

1. Field of the Invention

The present invention relates to an apparatus, and particularly to an apparatus and a method for testing an IEEE1394 port of a motherboard test device.

2. General Background

IEEE (Institute of Electrical and Electronic Engineers)1394 has two standard ports: an IEEE1394a port and an IEEE1394b port. The IEEE1394a port may provide 100 Mbps, 200 Mbps, and 400 Mbps data transmission rates. The IEEE1394b port extends data transmission rates of the IEEE1394a port, providing an 800 Mbps data transmission rate.

Motherboards must be tested for quality before shipment. Conventionally, in testing, a peripheral device is coupled to a motherboard test device under test via an IEEE1394a/b port to test whether the IEEE1394a/b function works well or not. For example, an ATA/ATAPI hard disk drive is coupled to the motherboard test device via an IEEE1394a/b port to test the IEEE1394 a/b port function. However, a conventional ATA/ATAPI hard disk drive is expensive, and this can increase the cost of testing. Furthermore, the ATA/ATAPI hard disk drive consumes significant amounts of power, and is prone to cause reliability problems especially if it sustains external shock or vibration. If the ATA/ATAPI hard disk drive operates unreliably, this may compromise the accuracy of the test.

What is needed is an apparatus and a method which economically and efficiently replaces a conventional ATA/ATAPI hard disk drive in the testing process of a motherboard test apparatus.

### SUMMARY

An exemplary apparatus for testing an IEEE1394 port of a motherboard test apparatus includes an IEEE1394 connector, a cable transceiver arbiter connected to the IEEE1394 connector, a first converting chip connected to the cable transceiver arbiter, a second converting chip connected to the first converting chip, and a flash chip connected to the second converting chip. The controller receives IEEE1394 signals from the connector, the first converting chip and the second converting chip cooperate to convert the IEEE1394 signals to flash signals, the flash signals are stored in the flash chip. The first converting chip and the second converting chip also cooperate to convert the flash signals to the IEEE1394 signals, the connector outputs the IEEE1394 signals through the controller. A method for testing an IEEE1394 port of a motherboard test apparatus is also provided.

Other advantages and novel features will become more apparent from the following detailed description, in which:

### BRIEF DESCRIPTION OF THE DRAWINGS

FIG. 1 is a schematic view of an apparatus for testing an IEEE1394 port of a motherboard test apparatus in accordance with a preferred embodiment of the present invention; and

FIG. 2 is a flowchart of steps involved in testing the motherboard test apparatus when using the apparatus of FIG. 1.

### DETAILED DESCRIPTION OF THE EMBODIMENT

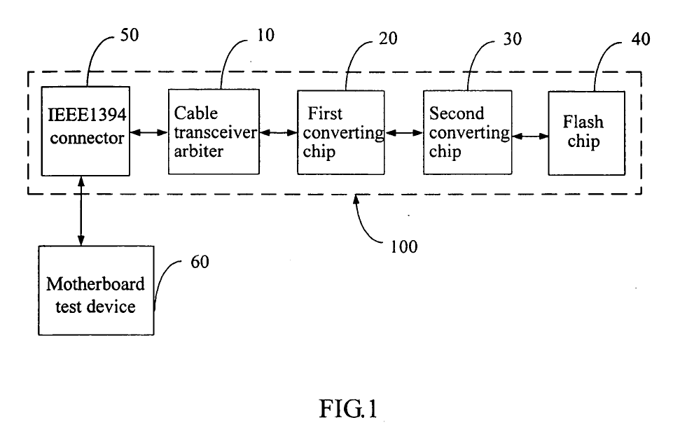

Referring to FIG. 1, an apparatus 100 for testing an IEEE1394 port of a motherboard test apparatus 60 in accordance with a preferred embodiment of the present invention includes an IEEE1394 connector 50, a cable transceiver arbiter 10, a first converting chip 20, a second converting chip 30, and a flash chip 40 used as a signal recorder, all of which are electrically connected in sequence. The IEEE1394 connector 50 is an IEEE1394a connector, an IEEE1394b connector, or both. The cable transceiver arbiter 10 is used for receiving IEEE1394 signals from the IEEE1394 connector 50 or outputting the IEEE1394 signals to the IEEE1394 connector 50. The first converting chip 20 is used for converting the IEEE1394 signals to integrated drive electronics (IDE) signals. The second converting chip 30 is used for converting the IDE signals to flash signals, and the flash signals are stored in the flash chip 40. The apparatus 100 exemplarily comprises a circuit substrate so that all of the IEEE1394 connector 50, the cable transceiver arbiter 10, the first and second converting chips 20, 30 and the flash chip 40 are able to be integrally mounted thereon and electrically connected with one another by means of circuits defined on the circuit substrate.

In this embodiment, the cable transceiver arbiter 10 is a model TSB81BA3-EP. The first converting chip 20 is a model OXFW912. The second converting chip 30 is a model SST55LD019A. The flash chip 40 is a model TC58DVM72A1FT00.

In testing, the apparatus 100 is connected to the IEEE1394a port of the motherboard test device 60 via the IEEE1394 connector 50. Workers input signals containing a file or files to the apparatus 100 via the motherboard test device 60, such as a host. Then, the apparatus 100 returns the signal containing the file or files to the motherboard test apparatus 60, the workers verify a size of the file or files input match a size of the file or files returned. For example, a 750 kB file is input to the apparatus 100, if a file returned by the apparatus 100 is the same size as the 750 kb file, the IEEE1394 port of the motherboard test apparatus 60 is considered to be okay. And if a returned file is any size other than the 750 kb file, then, the IEEE1394 port of the motherboard test apparatus 60 is considered to be bad.

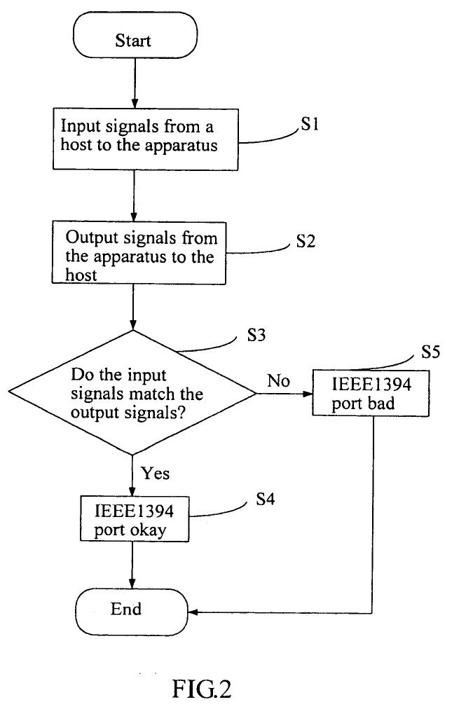

Referring also to FIG. 2, a method for testing the IEEE1394 port of the motherboard test apparatus 60 includes the steps of:

Step 1: signals containing a file is input from the motherboard test apparatus 60 to the apparatus 100, when the cable transceiver arbiter 10 receives the signals containing the file from the connector 50, it transmits the signals to the first converting chip 20; the first converting chip 20 converts the signals to IDE signals, and transmits the IDE signals to the second converting chip 30; the second converting chip 30 converts the IDE signals to flash signals, then, the flash signals are temporarily stored in the flash chip 40.

Step 2: the flash chip 40 transmits the flash signals to the second converting chip 30; the second converting chip 30 converts the flash signals to the IDE signals, and transmits the IDE signals to the first converting chip 20; the first converting chip 20 converts the IDE signals to return signals, and the return signals are transmitted to the motherboard test apparatus 60.

Step 3: workers compare the input signals containing the file with the return signals containing the file on a CRT screen of the motherboard test apparatus 60.

Step 4: if a size of the return signals containing the file matches a size of the input signals containing the file, the IEEE1394 port of the motherboard test device 60 is okay.

Step 5: if a size of the return signals containing the file do not match the size of the input signals containing the file, the IEEE1394 port of the motherboard test device 60 is bad.

When testing an IEEE1394b port of the motherboard 60, the procedure is the same as testing the IEEE1394a port. The apparatus 100 simulates the function of a conventional ATA/ATAPI hard disk drive in the test. The apparatus 100 is cheaper than the ATA/ATAPI hard disk drive, and more reliable, as well as consuming less power than the ATA/ATAPI hard disk drive.

It is believed that the present embodiment and it's advantages will be understood from the foregoing description, and it will be apparent that various changes may be made thereto without departing from the spirit and scope of the embodiment or sacrificing all of its material advantages, the example hereinbefore described merely being preferred or exemplary embodiment.

What is claimed is:

1. An apparatus for testing an IEEE1394 port of a motherboard test device, comprising:
an IEEE1394 connector;
a cable transceiver arbiter connected to the IEEE1394 connector;
a first converting chip connected to the cable transceiver arbiter;
a second converting chip connected to the first converting chip; and
a flash chip connected to the second converting chip, the controller receiving IEEE1394 signals from the connector, the first converting chip and the second converting chip cooperating to convert the IEEE1394 signals to flash signals, the flash signals being stored in the flash chip, and the first converting chip and the second converting chip cooperating to convert the flash signals to the IEEE1394 signals, the connector outputting the IEEE1394 signals through the controller.

2. The apparatus as claimed in claim 1, wherein the first converting chip is used for converting the IEEE1394 signals to integrated drive electronic (IDE) signals.

3. The apparatus as claimed in claim 2, wherein the second converting chip is used for converting the IDE signals to the flash signals.

4. The apparatus as claimed in claim 1, wherein the IEEE1394 connector is one of or combination of an IEEE1394a connector and an IEEE1394b connector.

5. A method for testing an IEEE1394 port of a motherboard test device, comprising the steps of:
providing an apparatus and electrically connecting the apparatus to the IEEE1394 port of the motherboard test device;
inputting signals containing a file or files from a motherboard test device to the apparatus, the apparatus converting the input signals to flash signals and storing the flash signals therein;
the apparatus converting the flash signals to return signals containing the file or files compatible to the IEEE1394 port of the motherboard test device, transmitting the return signals to the motherboard test device; and
comparing the input signals containing the file or files with the return signals containing the file or files, acquiring results.

6. The method as claimed in claim 5, wherein if a size of the return signals containing the file or files matches a size of the input signals containing the file or files, the IEEE1394 port of the motherboard test device is okay.

7. The method as claimed in claim 5, wherein if a size of the return signals containing the file or files do not match a size of the input signals containing the file or files, the IEEE1394 port of the motherboard test device is bad.

8. The method as claimed in claim 5, wherein the apparatus comprises an IEEE1394 connector, a cable transceiver arbiter, a first converting chip, a second converting chip, and a flash chip electrically connected in sequence.

9. The method as claimed in claim 8, wherein the step of converting the input signals to flash signals comprises:
the cable transceiver arbiter receiving the input signals from the IEEE1394 connector, and transmitting the input signals to the first converting chip;
the first converting chip converting the input signals to integrated drive electronics (IDE) signals, and transmitting the IDE signals to the second converting chip; and
the second converting chip converting the IDE signals to flash signals, and transmitting the flash signals to the flash chip, the flash chip storing the flash signals.

10. The method as claimed in claim 9, wherein the step of converting the flash signals to the return signals comprises:
the flash chip transmitting the flash signals to the second converting chip;
the second converting chip converting the flash signals to the IDE signals, and transmitting the IDE signals to the first converting chip;
the first converting chip converting the IDE signals to the return signals.

11. An apparatus for testing an IEEE1394 port of a device to be tested, comprising:
a circuit substrate;
an IEEE1394 compatible connector installable on said circuit substrate to perform further electrical connection with an IEEE1394 port of a device to be tested for input and output of IEEE1394 compatible signals between said apparatus and said device;
a cable transceiver arbiter integrally installable on said circuit substrate next to said IEEE1394 connector and electrically connectable with said IEEE1394 connector so as to retrieve input IEEE1394 signals from said IEEE1394 connector and transmit output IEEE1394 signals via said IEEE1394 connector; and
a signal recorder integrally installable on said circuit substrate next to said cable transceiver arbiter and electrically connectable with said cable transceiver arbiter so as to record said retrieved input IEEE1394 signals from said cable transceiver arbiter and allow said cable transceiver arbiter to read said recorded signals when said cable transceiver arbiter transmits said output IEEE1394 signals.

12. The apparatus as claimed in claim 11, further comprising at least one converting chip integrally installable on said circuit substrate and electrically connectable between said cable transceiver arbiter and said signal recorder for signal conversion.
